(19) United States
(12) Patent Application Publication
(10) Pub. No.: US 2016/0104840 A1
(43) Pub. Date: Apr. 14, 2016

(54) RESISTIVE MEMORY WITH A THERMALLY INSULATING REGION

(71) Applicants: Beth Cook, Meridien, ID (US); Nirmal Ramaswamy, Boise, ID (US); Shuichiro Yasuda, Peachtree CIty, GA (US); Scott Sills, Boise, ID (US); Koji Miyata, Peachtree City, GA (US)

(72) Inventors: Beth Cook, Meridien, ID (US); Nirmal Ramaswamy, Boise, ID (US); Shuichiro Yasuda, Peachtree CIty, GA (US); Scott Sills, Boise, ID (US); Koji Miyata, Peachtree City, GA (US)

(21) Appl. No.: 14/511,818

(22) Filed: Oct. 10, 2014

(51) Int. Cl. H01L 45/00

(52) U.S. Cl. CPC H01L 45/1293; H01L 45/1253; H01L 45/1233

(57) ABSTRACT

A resistive memory includes a memory cell having a first electrode, a second electrode and a resistive memory element between the first electrode and the second electrode. The memory cell includes a thermally insulating region. The thermally insulating region may be included in at least one electrode of the memory cell and/or within an electrically insulating region. The thermally insulating region can confine heat within the memory cell and thereby can reduce the current and/or voltage needed to write information in the resistive memory element.

### BACKGROUND

1. Technical Field

The techniques described herein relate to memories for storing information, and in particular to techniques for increasing a temperature of a memory cell having a resistive memory element. According to some embodiments, a thermally insulating region can be included in a memory cell to increase the temperature of the memory cell, which may allow reducing the voltage and/or current needed to write information to the memory cell.

2. Discussion of the Related Art

Memories are often used in computing devices and systems to store information, such as programs and/or program data. Various types of memory technologies have been developed, including various types of volatile and non-volatile memory. Volatile memory may require power to maintain the storage of information in the memory. A common example of volatile memory is dynamic random access memory (DRAM). Non-volatile memory, by contrast, is designed to maintain the information stored in the memory when power is not provided to the memory. A common example of non-volatile memory is flash memory (e.g., NAND flash memory).

### SUMMARY

Some embodiments relate to resistive memory that includes a memory cell. The memory cell includes a first electrode having a thermally insulating region, a second electrode, and a ReRAM memory element between the first electrode and the second electrode.

Some embodiments relate to resistive memory that includes a memory cell. The memory cell includes a first electrode, a second electrode, a ReRAM memory element between the first electrode and the second electrode, and a dielectric region comprising a thermally insulating material.

The foregoing summary is provided by way of illustration and is not intended to be limiting.

### BRIEF DESCRIPTION OF DRAWINGS

In the drawings, each identical or nearly identical component that is illustrated in various figures is represented by a like reference character. For purposes of clarity, not every component may be labeled in every drawing.

FIG. 1 is a plot illustrating the write voltage for a resistive memory cell vs. temperature.

FIG. 2A shows a resistive memory cell that includes a bottom electrode, a top electrode, and a resistive memory element between the bottom electrode and the top electrode.

FIGS. 2B, 2C and 2D show examples of resistive memory cells in which a thermally insulating region is included in the bottom electrode.

FIGS. 3A, 3B and 3C show examples of resistive memory cells in which a thermally insulating region is included in the top electrode.

FIGS. 4A, 4B, 4C and 4D show examples of resistive memory cells in which a thermally insulating dielectric material is included in the resistive memory cell.

FIGS. 5A, 5B and 5C show examples of resistive memory cells with at least one electrode that includes a thermally insulating region in which an electrically conducting material has a region of reduced cross-sectional area.

FIGS. 6A and 6B show examples of a resistive memory cells in which an electrode has a recess at least partially filled with an electrically insulating fill material.

FIG. 7 shows examples of resistive memory cells in which the top electrode includes a thermally insulating material, and the bottom electrode has a region of reduced cross-sectional area.

FIG. 8 shows a diagram of a memory, according to some embodiments.

FIG. 9 shows an electrical diagram of a memory cell, according to some embodiments.

### DETAILED DESCRIPTION

Various types of non-volatile memory have been developed that store information by changing the resistance of a resistive element within a memory cell. Memories that use such technologies will be referred to herein as “resistive memory.” Examples of resistive memory include resistive random access memory (ReRAM) and phase change memory (PCM).

ReRAM is a non-volatile resistive memory technology capable of producing high-speed memory devices. A ReRAM memory cell has a memory element with a variable resistance that may have hysteresis characteristics, i.e., it may change resistance when electrical energy is applied. Information can be written to ReRAM memory cells by changing the resistance of the variable resistance memory element. Various forms of variable resistance memory elements have been developed that are based on various dielectric materials, spanning from perovskites to transition metal oxides to chalcogenides. Even silicon dioxide has been shown to exhibit resistive switching capabilities. PCM is a non-volatile resistive memory technology in which the resistance of the memory element is changed by causing a change of phase in a phase change material of the resistive memory element. The phase of the phase change material may be changed by altering the crystal structure of the phase change material, e.g., from crystalline to amorphous, or from amorphous to crystalline. Information can be stored by providing a current to the PCM memory cell to induce the phase change. ReRAM, by contrast, does not rely upon inducing a phase change in a material of the resistive memory element. Some types of ReRAM memory cells may include an ionic resistive material. Application of a current to the ionic resistive material may cause migration of ions in the material, which changes its resistance.

To compete with other memory technologies, such as NAND flash, for example, which has been increasing the capacity of information that it can store on a chip, the information storage capacity of resistive memory is sought to be increased. To form resistive memories having a higher density of information storage, the size of the memory cell may need to be reduced, and the size of other supporting elements including the wiring, select transistors and spacing dielectrics between these elements also may need to be reduced.

One of the technical issues with resistive memory, such as ReRAM and PCM, is the high power needed to switch the resistive memory element between states. A write operation may require high power to be applied to the memory cell, which may require applying a relatively high voltage and/or current. Applying high voltages can cause reliability issues in dielectric materials, and applying high current can cause reliability issues in the transistors and wiring. These reliability issues can reduce product lifespans for resistive memories below commercially acceptable levels. Designing resistive memory cells such that write voltage, current and/or power can be reduced may allow an increase in product reliability for resistive memories, and thus provide an increase in product lifespan.

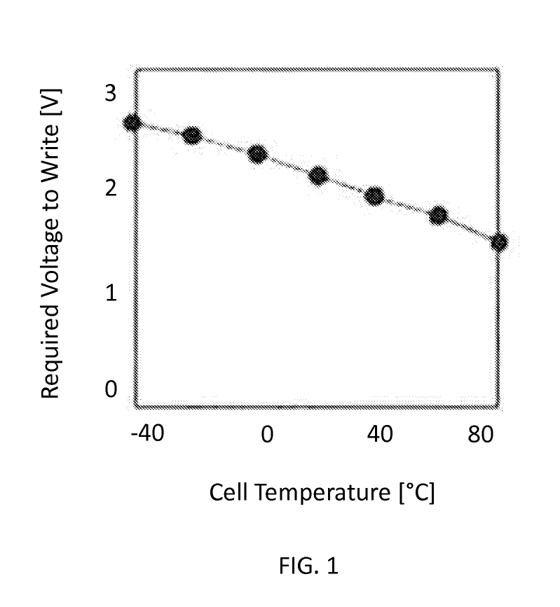

It has been appreciated that the voltage, current and/or power needed to write information into a resistive memory element decreases as the temperature increases, as changes in the properties of the resistive material can be accelerated at higher temperatures. FIG. 1 is a plot illustrating the write voltage vs. temperature in a ReRAM memory element. As shown in FIG. 1, if the temperature of the resistive memory element is increased, the write voltage can be reduced.

In some embodiments of the present application, a thermally insulating region is included in a resistive memory cell to increase the temperature of a resistive memory element. The thermally insulating region may be shaped and/or positioned within the resistive memory cell to prevent the conduction of heat out of the resistive memory cell, thereby confining joule heat in the resistive memory cell and increasing its temperature. By increasing the temperature of the resistive memory cell, the voltage, current and/or power needed to write data to a resistive memory cell can be decreased.

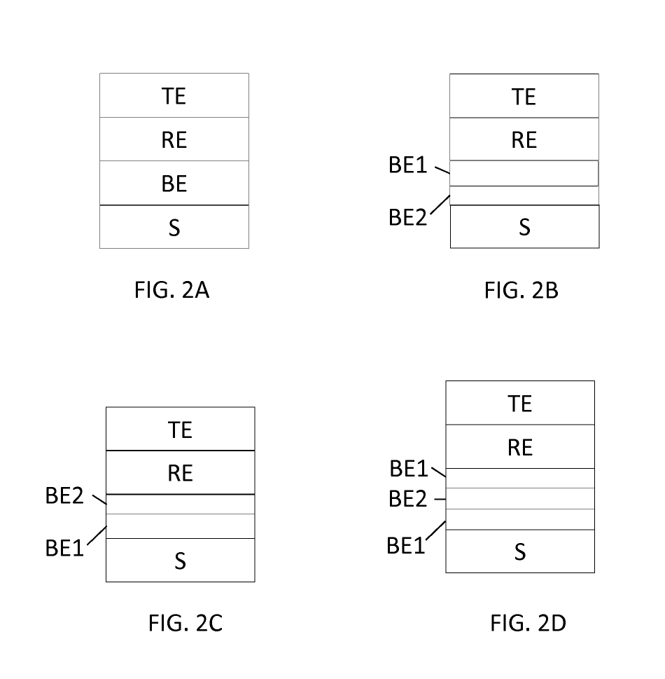

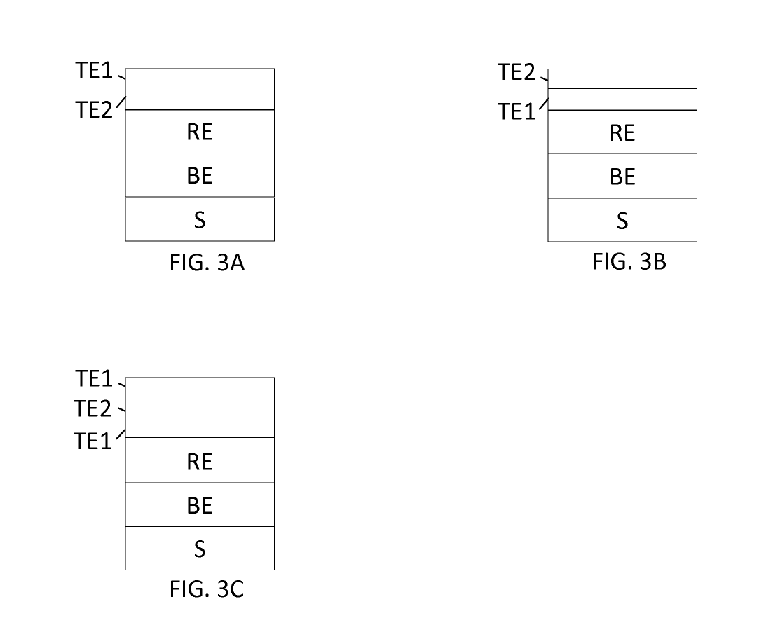

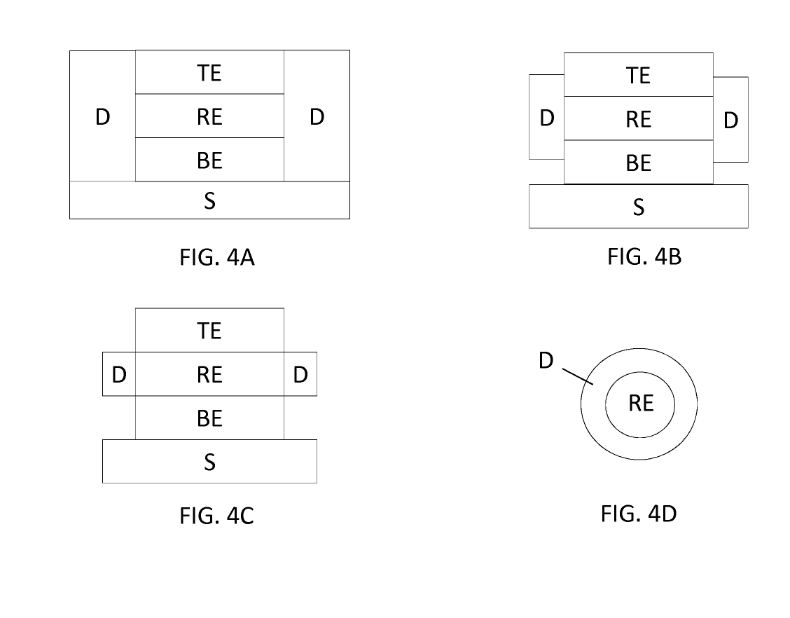

In some embodiments, a conductive electrode of the memory cell may include a thermally insulating region, as illustrated in FIGS. 2B-2D and 3A-3C. Prior to discussing FIGS. 2B-2D and 3A-3C, an example of a resistive memory cell will be described with reference to FIG. 2A.

FIG. 2A shows a resistive memory cell, according to some embodiments. As shown in FIG. 2A, the resistive memory cell includes a bottom electrode BE, a top electrode TE, and a resistive memory element RE between the bottom electrode BE and the top electrode TE. The resistive memory element RE may be formed of any suitable type of material that changes resistance when a sufficient current, voltage and/or power is applied, thereby storing information in the resistive memory element. In some embodiments, the resistive memory element RE may be a ReRAM memory element. It should be appreciated that suitable electronics, such as an access transistor, for example, may be included in each resistive memory cell. For simplicity of illustration, such electronics are not illustrated in the cross-sectional views of FIGS. 2-7.

As shown in FIG. 2A, bottom electrode BE may be formed over a substrate S, which can structurally support the memory. The substrate S may be formed of any suitable material(s). In some embodiments, the substrate S may include a semiconductor substrate, which may include any suitable layers formed thereon under the bottom electrode BE. The techniques described herein are not limited as to the material(s) forming substrate S. It should be appreciated that a resistive memory according to the techniques described herein may be formed of any number of memory cells, and may include an array of thousands, millions, or billions of memory cells or more, along with supporting electronics for reading and/or writing information to the memory cells.

As mentioned above, in some embodiments a conductive electrode of the memory cell may include a thermally insulating region. In some embodiments, a thermally insulating region may be included in the bottom electrode BE, the top electrode TE, or both the bottom electrode BE and the top electrode TE of the memory cell.

FIG. 2B shows an example of a resistive memory cell in which a thermally insulating region is included in the bottom electrode BE. In some embodiments, the bottom electrode BE may have two or more layers, e.g., BE1 and BE2, formed of different materials. The first bottom electrode layer BE1 may be formed of an electrically conductive material which may or may not be thermally insulating, and the second bottom electrode layer BE2 may be formed of an electrically conductive and thermally insulating material. In the example of FIG. 2B, the second bottom electrode layer BE2 of thermally insulating material is positioned below the first bottom electrode layer BE1. However, the techniques described herein are not limited in this respect, as in some embodiments the second electrode layer BE2 of thermally insulating material may be positioned above the first bottom electrode layer BE1, as shown in FIG. 2C. FIG. 2D shows an example of a resistive memory cell having a bottom electrode with three layers BE1, BE2 and BE1, in which the second electrode layer BE2 of thermally insulating material is between the two bottom electrode layers BE1.

The region of thermally insulating material may be included in a portion of the bottom electrode, as shown in FIGS. 2B, 2C and 2D, or may form the entire bottom electrode. If the region of thermally insulating material is included in a portion of the bottom electrode, it may be included in any part of the bottom electrode.

FIG. 3A shows an example of a resistive memory cell in which a thermally insulating region is included in the top electrode TE. In some embodiments, the top electrode TE may have two or more layers, e.g., TE1 and TE2, formed of different materials. The first top electrode layer TE1 may be formed of an electrically conductive material which may or may not be thermally insulating, and the second top electrode layer TE2 may be formed of an electrically conductive and thermally insulating material. In the example of FIG. 3A, the second top electrode layer TE2 of insulating material is positioned below the first top electrode layer TE1. However, the techniques described herein are not limited in this respect, as in some embodiments the second top electrode layer TE2 may be positioned above the first top electrode layer TE1, as shown in FIG. 3B. FIG. 3C shows an example of a top electrode with three layers TE1, TE2 and TE1, in which the top electrode layer TE2 of insulating material is positioned between the two top layers TE1.

The region of thermally insulating material may be included in a portion of the top electrode, as shown in FIGS. 3A, 3B and 3C, or may form the entire top electrode. If the region of thermally insulating material is included in a portion of the top electrode, it may be included in any part of the top electrode.

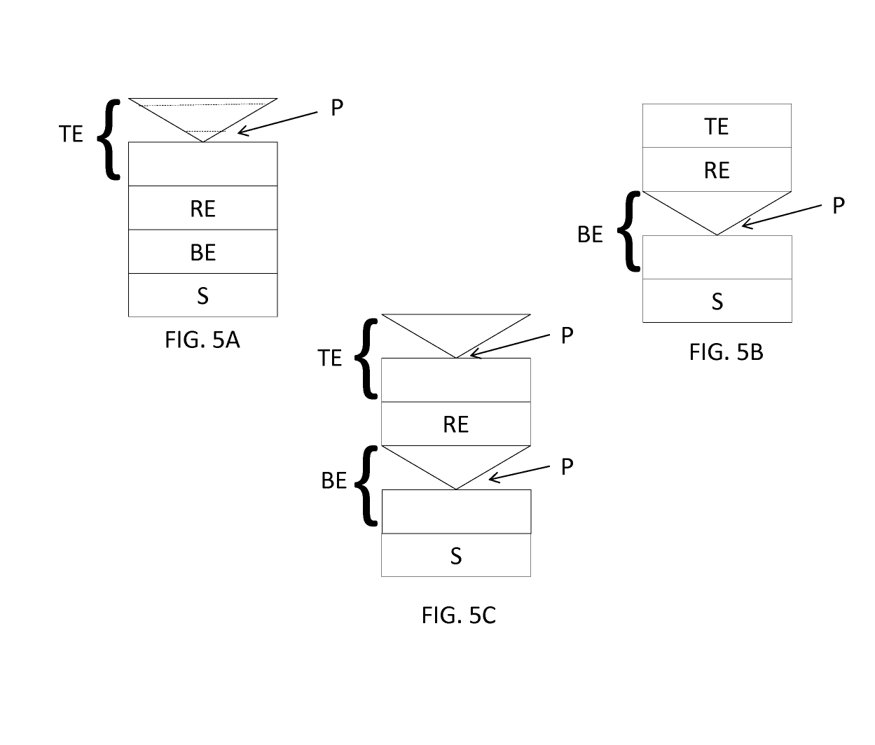

In some embodiments, regions of thermally insulating material may be included in both the top electrode TE and the bottom electrode BE, or may form the entire top electrode TE and bottom electrode BE. If regions of thermally insulating material are included in both the top electrode TE and the bottom electrode BE, any combination of the bottom electrode structures shown in FIGS. 2B-D and the top electrode structures shown in FIGS. 3A-3C, or any other combination of top and bottom electrode structures may be used, such as those shown in FIGS. 4-6.

Any of a variety of suitable thermally insulating materials may be included in an electrode (e.g., TE and/or BE). In some embodiments, a thermally insulating electrode layer (e.g., BE2 and/or TE2) may include a thermally insulating, electrically conductive material such as a titanium nitride TiN material, a tantalum nitride TaN material, a titanium carbon nitride TiCN material, a tantalum carbon nitride TaCN material, a titanium carbon oxynitride TiCON material, a tantalum carbon oxynitride TaCON material and/or a porous metal, by way of example. Such materials have sufficiently low thermal conductivities such that they are considered thermal insulators. In some embodiments, an electrically conducting electrode layer (e.g., BE1 and/or TE1), may include an electrically conductive material such as aluminum, copper and/or titanium, for example. However, in some embodiments electrically conducting electrode layer BE1 and/or TE1 may include a thermally insulating, electrically conductive material such as a titanium nitride TiN material, tantalum nitride TaN material and/or a porous metal, by way of example.

In some embodiments, a thermally insulating conductive material may have a thermal conductivity of less than 10 W/(m·K), such as less than 5 W/(m·K), for example.

In some embodiments, a memory cell may include an electrically insulating dielectric material that is thermally insulating, and which may be structured to confine heat within the resistive memory cell. Such an electrically and thermally insulating material may be included in addition to or as an alternative to including an electrically conductive, thermally insulating material in one or more electrodes. In some embodiments, a thermally insulating dielectric material may have a thermal conductivity of less than 1 W/(m·K), for example.

FIGS. 4A, 4B and 4C show examples of resistive memory cells in which a thermally insulating dielectric material D is included in the resistive memory cell. In the examples of FIGS. 4A, 4B and 4C, the thermally insulating dielectric material D is positioned to the side of the resistive memory element RE. In some embodiments, the thermally insulating dielectric material D may partially or completely surround the resistive memory element RE. For example, in some embodiments the thermally insulating dielectric material D may form a ring around the resistive memory element RE, as shown in the plan view of FIG. 4D (FIG. 4D is a plan view corresponding a cross-section of the resistive memory cells shown in FIGS. 4A, 4B and 4C). Optionally, the thermally insulating dielectric material D may contact the resistive memory element RE. The thermally insulating dielectric material D may extend for any suitable height in the vertical direction of FIGS. 4A, 4B and 4C. For example, the thermally insulating dielectric material D may extend from the bottom of the bottom electrode BE to the top of the top electrode TE, as shown in FIG. 4A. As another example, the thermally insulating dielectric material D may extend from an intermediate portion of the bottom electrode BE to an intermediate portion of the top electrode TE, as shown in FIG. 4B. In some embodiments, the thermally insulating dielectric material D may extend from the top of the bottom electrode BE to the bottom of the top electrode TE, as shown in FIG. 4C. The thermally insulating dielectric material D may extend in the vertical direction along the entire height of the resistive memory element RE, or may extend for only a portion of the height of the resistive memory element RE, in some embodiments. The thermally insulating dielectric material D may be formed of any suitable thermally and electrically insulating material. In some embodiments, the thermally insulating dielectric material D may include a porous silica material, a carbon material (e.g., carbon black), an SiCO material and/or a polymer material (e.g., polytetrafluoroethylene), such as a porous polymer material, for example. In some embodiments, the thermally insulating dielectric material D may be a gas (e.g., air) or vacuum. Such a gas or vacuum may be formed within a cavity. In some embodiments, the cavity may be formed at least partially around the resistive memory element.

In some embodiments, an electrode may include a thermally insulating region in which an electrically conducting material has a region of reduced cross-sectional area. The region of reduced cross-sectional area can impede the conduction of heat out of the memory cell through the electrode. Such a region of reduced cross-sectional area may be formed of any suitable material, including materials with high thermal conductivity. However, the techniques described herein are not limited in this respect, as in some embodiments the region of reduced cross-sectional area may be formed of a thermally insulating material.

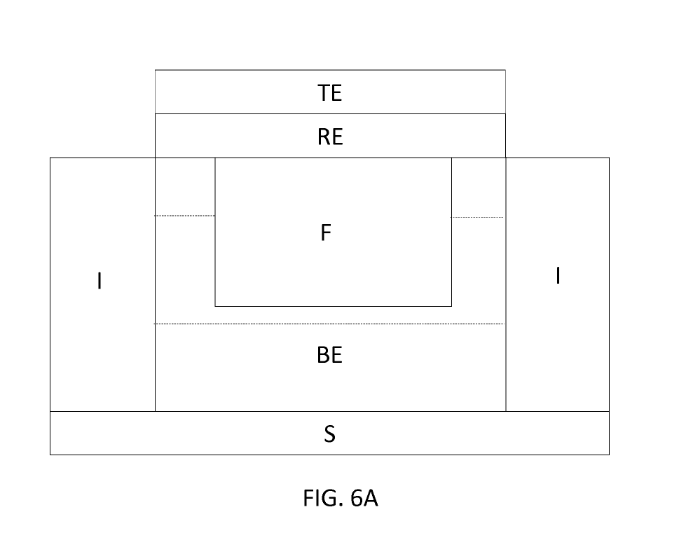

FIGS. 5A-5C show examples of resistive memory cells with at least one electrode that includes a thermally insulating region in which an electrically conducting material has a region of reduced cross-sectional area.

FIG. 5A shows an example of a resistive memory cell in which the top electrode TE has a “pinched” region P of reduced cross-sectional area (along the lower dashed line) with respect to the upper portion of the top electrode TE (along the upper dashed line). As shown in FIG. 5A, the cross-sectional area is perpendicular to the direction of current flow through the electrode, as current flow is in the vertical direction of FIG. 5A. The pinched region P reduces the capability of the top electrode TE to conduct heat from the interior of the resistive memory cell to the exterior of the resistive memory cell. FIG. 5B shows an example in which the bottom electrode BE has a pinched region P. FIG. 5C shows an example in which both the top electrode TE and the bottom electrode BE have pinched regions P. In some embodiments, the area adjacent the pinched region P between the regions of the electrode having a larger cross section may be filled with a dielectric material, such as a thermally insulating dielectric material, for example.

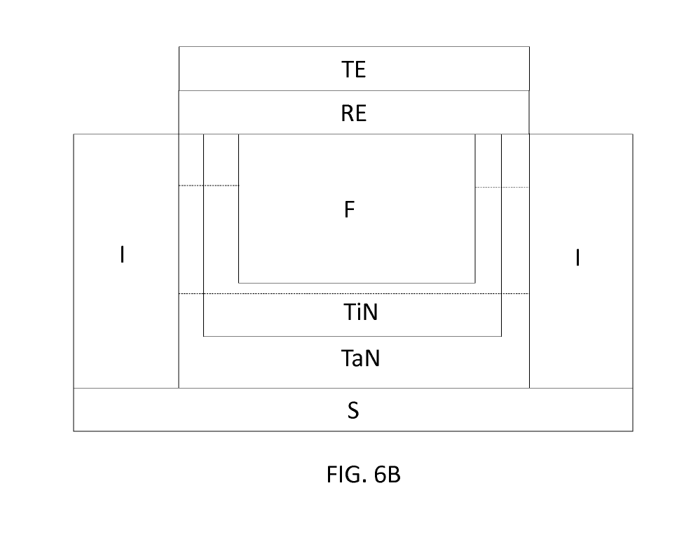

In some embodiments, a resistive memory cell may include an electrode that has a recess filled with a dielectric material, as shown in FIGS. 6A and 6B. The embodiments of FIG. 6A and FIG. 6B show an example of providing heat insulation with a reduced cross-sectional area of a portion of an electrode (along the upper dashed line) with respect to the cross-sectional area of another portion of the electrode (along the lower dashed line).

FIG. 6A shows an embodiment of a resistive memory cell in which the bottom electrode BE has a recess formed therein. In some embodiments, the recess may be at least partially filled with an electrically insulating fill material F as a dielectric region. The recess may have any suitable shape. In some embodiments, the recess may have a circular cross-section, and the bottom electrode BE may form a ring around the recess. The bottom electrode BE may be at least partially surrounded by a dielectric material I which is electrically insulating. Optionally, the top electrode TE and/or the bottom electrode BE may include an electrically conducting, thermally insulating material, as discussed above.

To form the resistive memory cell of FIG. 6A, a recess may be formed in the bottom electrode BE, then the recess may be filled with the fill material F. The top surface of the structure may then be planarized (e.g., using chemical-mechanical polishing) so that the uppermost portion of the bottom electrode BE is co-planar with the top of the fill material F. The resistive memory element RE and top electrode TE may then be formed. However, the techniques described herein are not limited as to any particular technique for forming the resistive memory cell.

In some embodiments, the fill material F may include an electrically insulating material such as a silicon nitride (SiN) material. In some embodiments, the fill material F may be both electrically and thermally insulating. Examples of fill materials F that are both electrically and thermally insulating include a porous silica material, a carbon material (e.g., carbon black), an SiCO material and/or a polymer material (e.g., polytetrafluoroethylene), such as a porous polymer material. Insulating material I may be formed of any suitable electrically insulating material, such as silicon nitride, silicon oxide or any other suitable insulating material. Optionally, the insulating material I may be a thermally insulating dielectric material.

FIG. 6B shows an embodiment of a resistive memory cell in which the bottom electrode BE has a recess formed therein, and the bottom electrode BE includes two layers. In the example of FIG. 6B, the bottom electrode BE includes a layer of a TiN material formed on a layer of TaN material. In some embodiments, the layer of TaN material may include TaCON (Tantalum Carbon Oxynitride).

A memory element as illustrated in FIG. 6B has been fabricated to be 600 Angstrom in diameter with a TaN layer having a thickness of 35 Angstroms deposited by atomic layer deposition (ALD), a TiN layer having a thickness of 50 Angstroms deposited by atomic layer deposition (ALD), and silicon nitride (SiN) as the fill material F. Such a device was tested and demonstrated to have a significant reduction (˜2-3x) in the percentage of post-long term storage bit fails over a similar structure with TaN as the fill material F, which demonstrates a reduced bit error rate and improved reliability when using a dielectric material such as SiN as the fill material F.

In some embodiments, such as those illustrated in FIGS. 6A and 6B, the region of reduced cross-sectional area (e.g., pinched region P) may have a cross-sectional area of 1/2, or less than 1/2, of the cross-sectional area of another region of the same electrode.

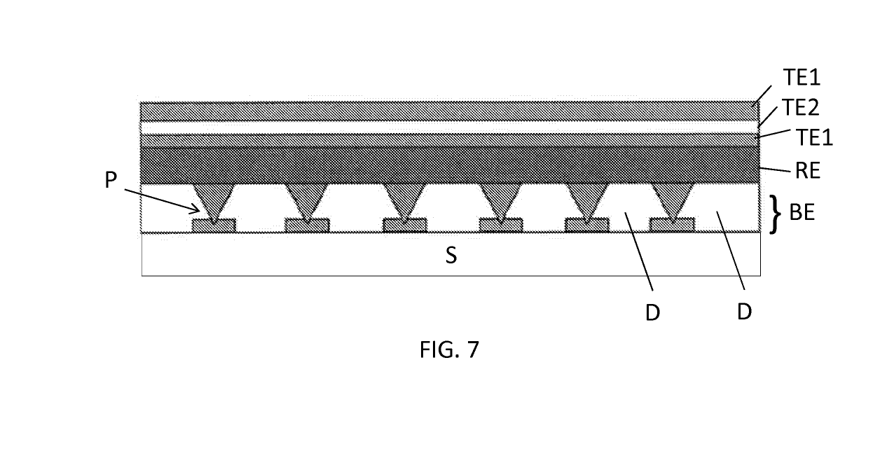

In some embodiments, a resistive memory cell may include a plurality of thermally insulating regions. FIG. 7 shows an example of a resistive memory in which the top electrode TE includes a thermally insulating material TE2, as in FIG. 3C, and the bottom electrode BE in each resistive memory cell has a pinched region P of reduced cross-sectional area, as in FIG. 6B. In the example of FIG. 7, a plurality of memory cells share a common layer including resistive element RE, and also share a common top electrode TE. FIG. 7 also shows a thermally insulating dielectric material D may be included which separates the respective memory cells.

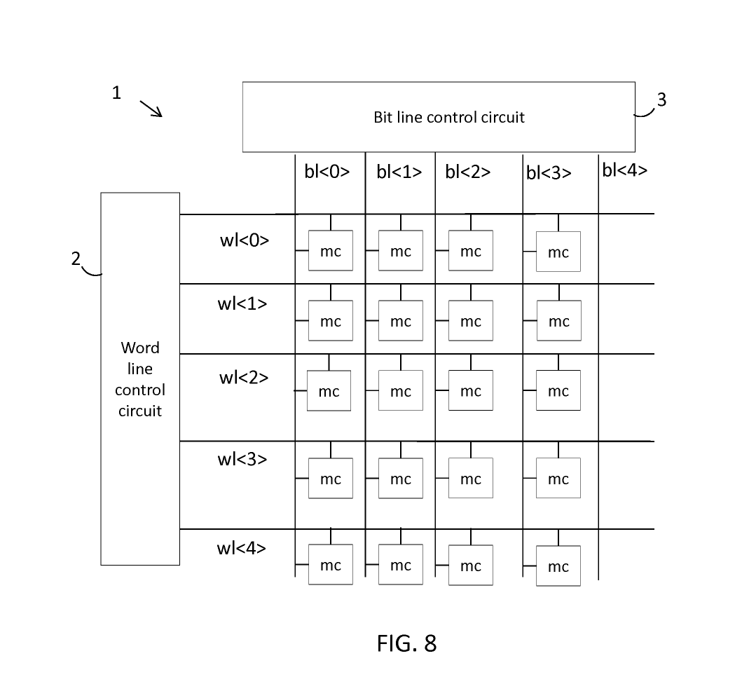

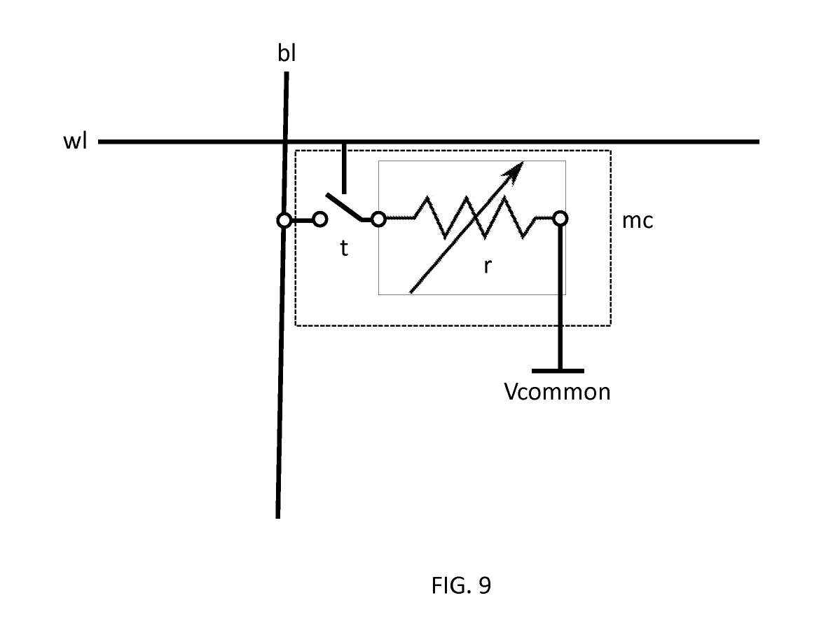

A memory including resistive memory cells may have any suitable structure and supporting electronics, an example of which will be described with reference to FIGS. 8 and 9.

FIG. 8 shows a diagram of a memory 1, according to some embodiments. Memory 1 includes an array of resistive memory cells mc arranged in rows and columns. Each memory cell mc is connected to a word line w1 and a bit line b1. The word line control circuit 2 and bit line control circuit 3 address selected memory cell(s) of the array by selecting a corresponding word line and bit line. The word lines wl and bit lines b1 control writing data into the memory cells mc by applying suitable voltages to the word lines wl and bit lines b1. The word lines wl and bit lines b1 also control reading data from the memory cells mc by applying suitable voltages to the word lines wl and reading out the data through the bit lines b1. The memory cells mc may be any suitable resistive memory cells using any of a variety of technologies, examples of which include resistive random access memory (ReRAM) and phase-change memory (PCM), for example.

FIG. 9 shows an electrical diagram of an exemplary memory cell mc, according to some embodiments. As shown in FIG. 9, memory cell mc has a transistor t and a resistive element r. In the example of FIG. 9, the transistor t is an access transistor that controls access to the memory cell mc. Any suitable type of transistor may be used, such as a field effect transistor (FET) or a bipolar transistor, by way of example. Transistor t has a first terminal connected to a bit line bl, a second terminal connected to a first terminal of the resistive element r and a control terminal connected to the word line w1. The second terminal of the resistive element r is connected to a common voltage node Vcommon. In this example, memory cell mc is a three-terminal device connected to the bit line b1, word line wl and common voltage node Vcommon.

Information can be written into a resistive memory cell by applying a current through the resistive element r of the memory cell mc. When a voltage is applied across the memory cell between the bit line b1 and the common voltage node Vcommon, the current through the resistive element r can be controlled by controlling the voltage applied to the control terminal of the transistor t by the word line w1.

The techniques described herein are not limited as to the particular configuration of the memory and supporting electronics shown in FIGS. 8 and 9. Any suitable electronics may be used for writing information to and reading information from the resistive memory element, the design of which is understood by those of ordinary skill in the art.

The techniques and apparatus described herein are not limited in its application to the details of construction and the arrangement of components set forth in the foregoing description or illustrated in the drawings. The techniques and apparatus described herein are capable of other embodiments and of being practiced or of being carried out in various ways. Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

In the claims, the phrase “at least one of” means one or more of the elements following the phrase. For example, the phrase “at least one of A, B and C” means A, B, or C, or any combination of A, B and C.

Having thus described at least one illustrative embodiment of the invention, various alterations, modifications, and improvements will readily occur to those skilled in the art. Such alterations, modifications, and improvements are intended to be within the spirit and scope of the invention. Accordingly, the foregoing description is by way of example only and is not intended as limiting. The invention is limited only as defined in the following claims and the equivalents thereto.

What is claimed is:

1. A resistive memory comprising:
a memory cell, including:
a first electrode having a thermally insulating region;
a second electrode; and
a ReRAM memory element between the first electrode and the second electrode.

2. The resistive memory of claim 1, wherein the thermally insulating region comprises a thermally insulating material.

3. The resistive memory of claim 2, wherein the thermally insulating material comprises at least one of a titanium nitride material, a tantalum nitride material, a titanium carbon nitride material, a tantalum carbon nitride material, a titanium carbon oxynitride material, a tantalum carbon oxynitride material and a porous metal.

4. The resistive memory of claim 1, wherein the thermally insulating region comprises a first region of the first electrode having a cross-sectional area less than that of a second region of the first electrode.

5. The resistive memory of claim 4, further comprising a dielectric material that at least partially fills a cavity in the first electrode.

6. The resistive memory of claim 5, wherein the dielectric material comprises at least one of a porous silica material, a silicon nitride material, a carbon material, an SiCO material and a polymer material.

7. The resistive memory of claim 4, wherein the first region has a cross-sectional area less than ½ of that of the second region.

8. The resistive memory of claim 1, wherein the thermally insulating region comprises a thermally insulating material having a thermal conductivity of less than 10 W/(m·K).

9. The resistive memory of claim 1, wherein the thermally insulating region is structured to confine heat within the memory cell.

10. A resistive memory comprising:
a memory cell, including:
a first electrode;
a second electrode;
a ReRAM memory element between the first electrode and the second electrode; and
a dielectric region comprising a thermally insulating material.

11. The resistive memory of claim 10, wherein the thermally insulating material comprises at least one a porous silica material, a carbon material, an SiCO material and a polymer material.

12. The resistive memory of claim 10, wherein the dielectric region at least partially surrounds the ReRAM memory element.

13. The resistive memory of claim 10, wherein the dielectric region contacts the ReRAM memory element.

14. The resistive memory of claim 10, wherein the dielectric region electrically insulates the ReRAM memory element from a second ReRAM memory element of the resistive memory.

15. The resistive memory of claim 10, wherein the dielectric region comprises a gas or a vacuum.

16. The resistive memory of claim 10, wherein the thermally insulating material has a thermal conductivity of less than 1 W/(m·K).
